(19) United States
(12) Patent Application Publication
(10) Pub. No.: US 2004/0127054 A1
(43) Pub. Date: Jul. 1, 2004

(54) Method for manufacturing magnetic random access memory

(76) Inventors: Kye Nam Lee, Icheon-si (KR); In Woo Jang, Seoul (KR)

Correspondence Address: HELLER EHRMAN WHITE & MCAULIFFE LLP, 1666 K STREET,NW, SUITE 300, WASHINGTON, DC, 20006, US

(21) Appl. No.: 10/608,081

(22) Filed: Jun. 30, 2003

(30) Foreign Application Priority Data
Dec. 30, 2002 (KR) 2002-87083

(51) Int. Cl. H01L 21/302; H01L 21/461

(52) U.S. Cl. 438/712

(57) ABSTRACT

A method for manufacturing a MRAM wherein a MTJ cell and a connection layer are simultaneously patterned, and an insulating film spacer and a hard mask layer are used as etching masks instead of a photoresist film to simplify the manufacturing process and to prevent generation of a metal polymer is disclosed. The method for manufacturing a MRAM comprises the steps of: forming a metal layer for a connection layer connected to a semiconductor substrate through a lower insulating layer; sequentially forming a pinned magnetic layer, a tunnel barrier layer and a free magnetic layer on the metal layer; forming a hard mask on the free magnetic layer; etching the hard mask layer and the free magnetic layer in a photolithogrphy process using a MTJ cell mask to expose the tunnel barrier layer; sequentially forming a barrier layer and an insulating film on the entire surface; anisotropically etching the insulating film to form an insulating film spacer on a sidewall of the hard mask layer and the free magnetic layer; and etching the tunnel barrier layer, the pinned magnetic layer and the metal layer using the insulating film spacer and the hard mask layer as a mask to form a MTJ cell and a connection layer.

### BACKGROUND OF THE INVENTION

1. Field of the Invention

The present invention generally relates to a method for manufacturing a magnetic RAM (hereinafter, referred to as “MRAM”), and more specifically, to a method for manufacturing a MRAM, wherein a MTJ cell and a connection layer are simultaneously patterned, and an insulating film spacer and a hard mask layer are used as etching masks instead of a photoresist film to simplify the manufacturing process and to prevent generation of a metal polymer, thereby improving characteristics and reliability of a device.

2. Description of the Prior Art

Most of the semiconductor memory manufacturing companies have developed the MRAM using a ferromagnetic material as one of the next generation memory devices.

The MRAM is a memory device for reading and writing information. It has multi-layer ferromagnetic thin films, and operates by sensing current variations according to a magnetization direction of the respective thin film. The MRAM has high speed and low power consumption, and allows high integration density due to the special properties of the magnetic thin film. The MRAM also performs a nonvolatile memory operation similar to a flash memory.

The MRAM is a memory device which uses a giant magneto resistive (GMR) phenomenon or a spin-polarized magneto-transmission (SPMT) generated when the spin influences electron transmission.

The MRAM using the GMR utilizes the phenomenon that resistance is remarkably varied when spin directions are different in two magnetic layers having a non-magnetic layer therebetween to implement a GMR magnetic memory device.

The MRAM using the SPMT utilizes the phenomenon that larger current transmission is generated when spin directions are identical in two magnetic layers having an insulating layer therebetween to implement a magnetic permeable junction memory device.

The MRAM comprises a transistor and a MTJ cell.

FIGS. 1a through 1g are cross-sectional diagrams illustrating a conventional method for manufacturing a MRAM.

Referring to FIG. 1a, a lower insulating layer 11 is formed on a semiconductor substrate (not shown). The lower insulating film 11 is an insulating film planarizing the entire surface of the semiconductor substrate having a device isolation film (not shown), a transistor (not shown) comprising a first wordline which is a read line and a source/drain region, a ground line (not shown), a conductive layer (not shown), and a second wordline (not shown) which is a write line thereon.

Next, a metal layer 13 for a connection layer connected to the conductive layer is formed. Preferably, the metal layer 13 for a connection layer comprises metals such as W, Al, Pt, Cu, Ir and Ru, which are used in conventional semiconductor devices.

Thereafter, a MTJ layer 12 is deposited on the metal layer 13 for a connection layer. The MTJ layer 12 comprises a stacked structure of a pinned magnetic layer 15, a tunnel barrier layer 17 and a free magnetic layer 19. The pinned magnetic layer 15 and the free magnetic layer 19 are preferably magnetic materials such as CO, Fe, NiFe, CoFe, PtMn and IrMn.

Thereafter, a first hard mask layer 21 is formed on the MTJ layer 12.

Referring to FIG. 1b, a first photoresist film pattern 23 is formed on the first hard mask layer 21 via an exposure and development process using a MTJ cell mask (not shown).

Referring to FIG. 1c, the first hard mask layer 21 and the free magnetic layer 19 are etched using the first photoresist pattern 23 as a mask. A polymer 25 is generated to be attached to a sidewall of the free magnetic layer 19 and the first hard mask layer 21 in the etching process.

Referring to FIGS. 1d and 1e, the first photoresist film pattern 23 is removed, and a second hard mask layer 27 is then formed on the entire surface of the resulting structure.

Referring to FIGS. 1f and 1g, a second photoresist film pattern 29 is formed on the second hard mask layer 27 via an exposure and development process using a connection layer mask (not shown). Thereafter, the tunnel barrier layer 17, the pinned magnetic layer 15 and the metal layer 13 for a connection layer is patterned using the second photoresist pattern 29 to form a metal layer 13 pattern and a MTJ cell.

Referring to FIGS. 1g and 2, since layers formed of different materials, i.e. the pinned magnetic layer 15 and the metal layer 13 are simultaneously etched in the patterning process, a non-volatile reaction product 31 is generated during the etching of magnetic materials. The non-volatile reaction product 31 piles up on the second photoresist pattern 29 and the layers being etched, which maks the etching process difficult. Additionally, a metal polymer 33 becomes attached to the first hard mask layer 21, the second mask layer 27, and on the top and sidewall of the lower insulating layer 11. When the resulting structure is cleaned via a cleaning process to completely remove the reaction product 33, an undercut, indicated as “A” in FIG. 1g, is generated.

By-products such as the metal polymer 33 generated in the etching process degrade characteristics and reliability of a device. Moreover, the undercut of the metal layer 13 degrades yield and productivity of a device.

### SUMMARY OF THE INVENTION

It is an object of the present invention to provide a method for manufacturing a MRAM wherein a MTJ cell and a connection layer are simultaneously patterned, and an insulating film spacer and a hard mask layer are used as etching masks instead of a photoresist film to simplify the manufacturing process and to prevent generation of a metal polymer, thereby improving characteristics and reliability of a device.

In order to achieve the above object of the present invention, there is provided a method for manufacturing a MRAM, comprising the steps of: forming a metal layer for a connection layer connected to a semiconductor substrate through a lower insulating layer; sequentially forming a pinned magnetic layer, a tunnel barrier layer and a free magnetic layer on the metal layer; forming a hard mask on the free magnetic layer; etching the hard mask layer and the free magnetic layer in a photolithogrphy process using a MTJ cell mask to expose the tunnel barrier layer; sequentially forming a barrier layer and an insulating film on the entire surface; anisotropically etching the insulating film to form an insulating film spacer on a sidewall of the hard mask layer and the free magnetic layer; and etching the tunnel barrier layer, the pinned magnetic layer and the metal layer using the insulating film spacer and the hard mask layer as a mask to form a MTJ cell and a connection layer.

### BRIEF DESCRIPTION OF THE DRAWINGS

FIGS. 1a through 1g are cross-sectional diagrams illustrating a conventional method for manufacturing a MRAM.

FIG. 2 is a SEM photograph illustrating a MRAM fabricated in accordance with the conventional method.

FIGS. 3a through 3d are cross-sectional diagrams illustrating a method for manufacturing a MRAM in accordance with the present invention.

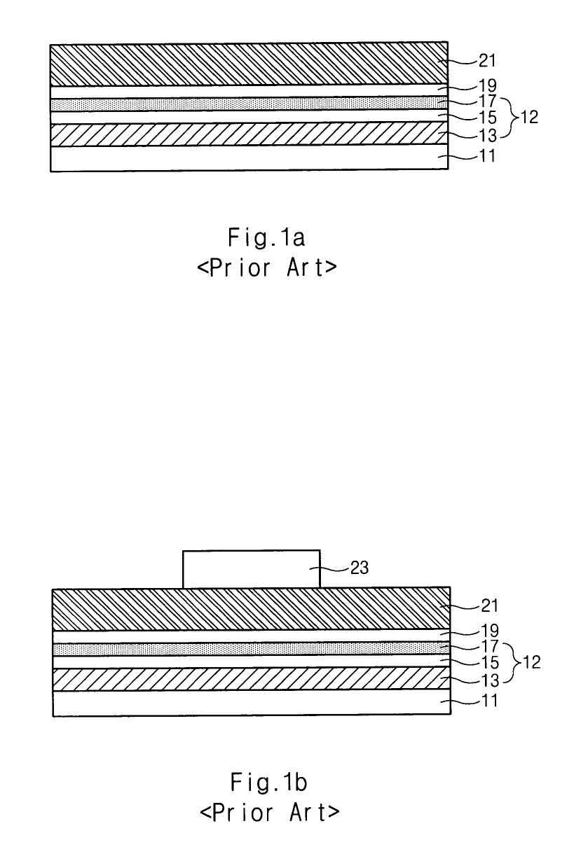

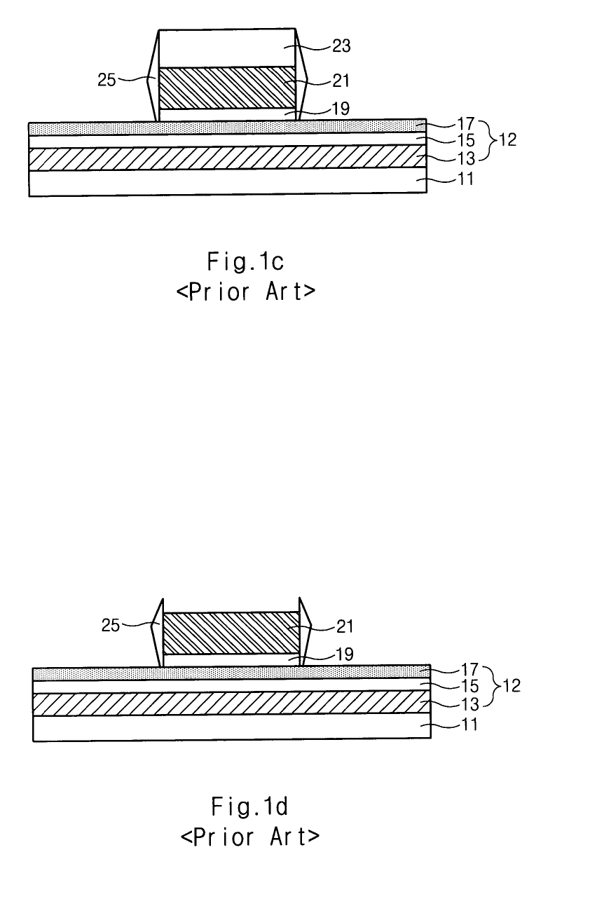

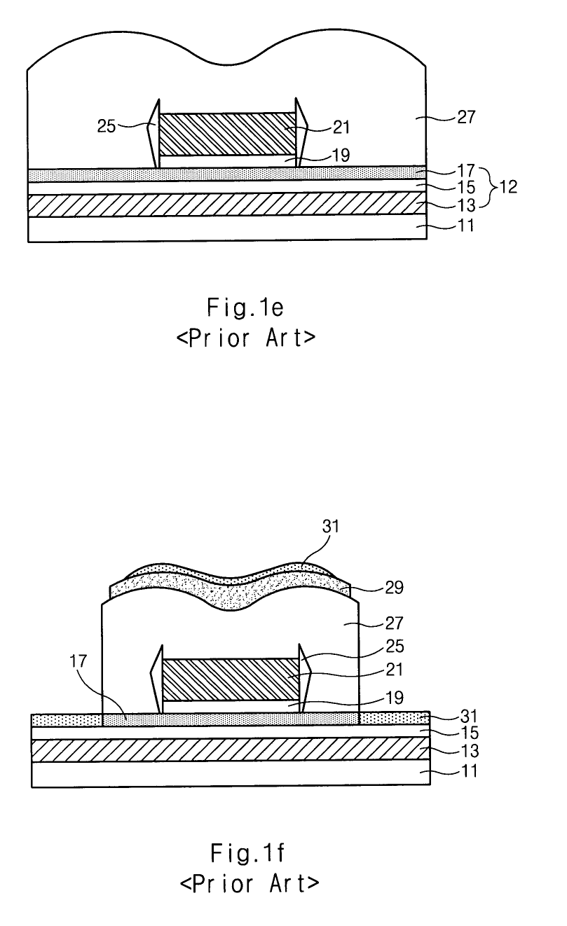

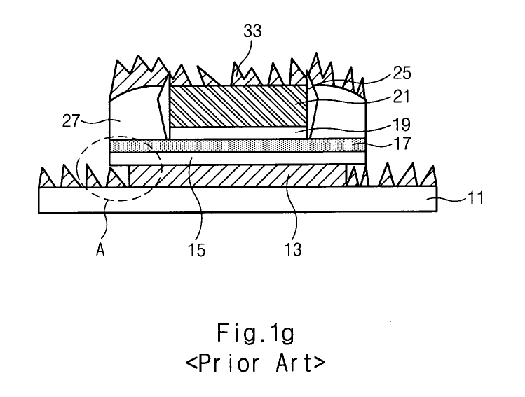

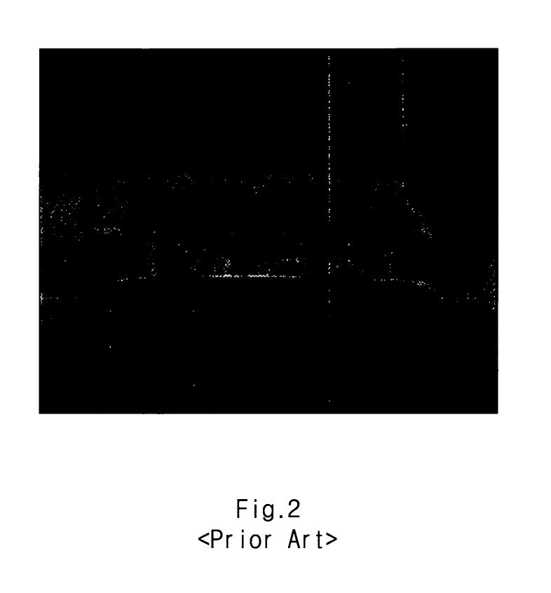

### DETAILED DESCRIPTION OF THE PREFERRED EMBODIMENTS

The present invention will be explained in detail referring to the accompanying drawings.

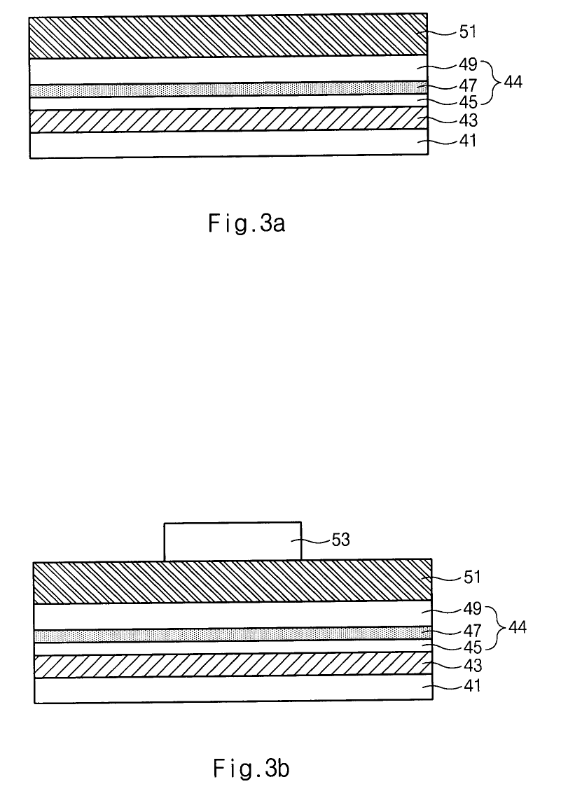

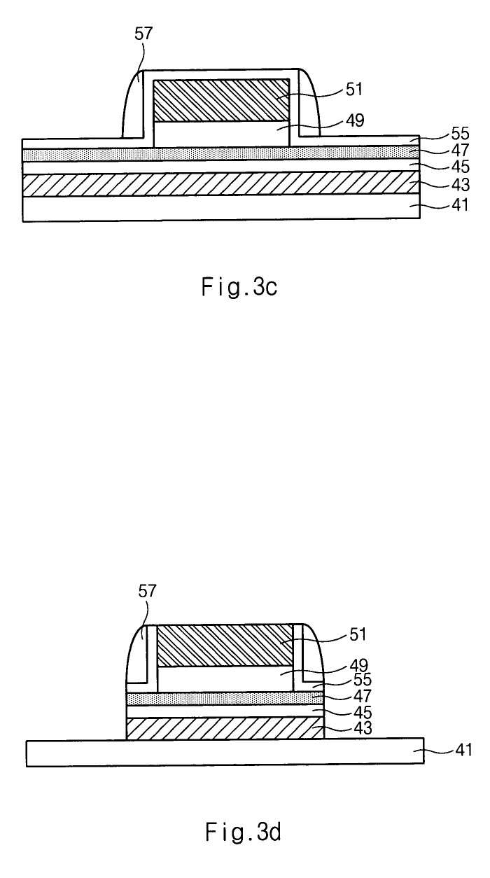

FIGS. 3a through 3d are cross-sectional diagrams illustrating a method for manufacturing a MRAM in accordance with the present invention.

Referring to FIG. 3a, a lower insulating layer 41 is formed on a semiconductor substrate (not shown). The lower insulating film 41 is an insulating film planarizing the entire surface of the semiconductor substrate having a device isolation film (not shown), a transistor (not shown) comprising a first wordline which is a read line and a source/drain region, a ground line (not shown), a conductive layer (not shown), and a second wordline (not shown) which is a write line thereon.

Next, a metal layer 43 for a connection layer connected to the conductive layer is formed. Preferably, the metal layer 43 for a connection layer comprises metals such as W, Al, Pt, Cu, Ir and Ru, which are used in conventional semiconductor devices.

Thereafter, a MTJ layer 44 is deposited on the metal layer 43 for a connection layer. The MTJ layer 44 comprises a stacked structure of a pinned magnetic layer 45, a tunnel barrier layer 47 and a free magnetic layer 49.

The pinned magnetic layer 45 and the free magnetic layer 49 are preferably formed of magnetic materials such as CO, Fe, NiFe, CoFe, PtMn and IrMn. The tunnel barrier layer 47 preferably has a thickness of less than 2 nm which is the minimum thickness required for data sensing.

Next, a first hard mask layer 51 is formed on the MTJ layer 44.

Referring to FIG. 3b, a first photoresist film pattern 53 is formed on the first hard mask layer 51 via an exposure and development process using a MTJ cell mask (not shown).

Referring to FIG. 3c, the first hard mask layer 51 and the free magnetic layer 49 are etched using the first photoresist film pattern 53 as a mask. A polymer which may be generated in the etching process is removed.

Thereafter, the first photoresist film pattern 53 is removed, and a barrier layer 55 is then formed on the entire surface of the resulting structure. The barrier layer 55 is preferably formed of TiN, TaAlN or TiON.

An oxide film or a nitride film (not shown) having a predetermined thickness are deposited on the entire surface of the resulting structure, and then anisotropically etched to form an insulating film spacer 57.

Referring FIG. 3d, the tunnel barrier layer 47, the pinned magnetic layer 45 and the metal layer 43 are patched using the hard mask layer 51 and the insulating film spacer 57 as a mask to simultaneously form a MTJ cell is and a metal layer.

As discussed earlier, according to the present invention, a MTJ cell and a connection layer are simultaneously patterned, and an insulating film spacer and a hard mask layer are used as etching masks instead of a photoresist film to simplify the manufacturing process and to prevent generation of a metal polymer, thereby improving characteristics and reliability of a device.

What is claimed is:

1. A method for manufacturing a MRAM, comprising the steps of:
forming a metal layer for a connection layer connected to a semiconductor substrate through a lower insulating layer;
sequentially forming a pinned magnetic layer, a tunnel barrier layer and a free magnetic layer on the metal layer;
forming a hard mask on the free magnetic layer;
etching the hard mask layer and the free magnetic layer in a photolithogrphy process using a MTJ cell mask to expose the tunnel barrier layer;
sequentially forming a barrier layer and an insulating film on the entire surface;
anisotropically etching the insulating film to form an insulating film spacer on a sidewall of the hard mask layer and the free magnetic layer; and
etching the tunnel barrier layer, the pinned magnetic layer and the metal layer using the insulating film spacer and the hard mask layer as a mask to form a MTJ cell and a connection layer.

2. The method according to claim 1, wherein the barrier layer is a TiN layer, a TiON layer or a Ta layer.

3. The method according to claim 1, wherein the insulating film is an oxide film or a nitride film.
